(19) United States
(12) Patent Application Publication
(10) Pub. No.: US 2014/0162194 A1
(43) Pub. Date: Jun. 12, 2014

(54) CONFORMAL SACRIFICIAL FILM BY LOW TEMPERATURE CHEMICAL VAPOR DEPOSITION TECHNIQUE

(71) Applicant: APPLIED MATERIALS, INC., Santa Clara, CA (US)

(72) Inventors: Jingjing XU, San Jose, CA (US); Joe Griffith CRUZ, San Jose, CA (US); Pramit MANNA, Santa Clara, CA (US); Deenesh PADHI, Sunnyvale, CA (US); Bok Hoen KIM, San Jose, CA (US); Barry L. CHIN, Saratoga, CA (US)

(73) Assignee: APPLIED MATERIALS, INC., Santa Clara, CA (US)

(21) Appl. No.: 13/897,270

(22) Filed: May 17, 2013

Related U.S. Application Data
(60) Provisional application No. 61/652,131, filed on May 25, 2012.

(51) Int. Cl. G03F 7/16

(52) U.S. Cl. CPC G03F 7/167
USPC 430/403; 430/432; 156/345.11

(57) ABSTRACT

Methods and apparatus for forming a sacrificial during a novel process sequence of lithography and photoresist patterning are provided. In one embodiment, a method of processing a substrate having a resist material and an anti-reflective coating material thereon includes depositing an organic polymer layer over the surface of the substrate inside a process chamber using a CVD technique. The CVD technique includes flowing a monomer into a processing region of the process chamber, flowing an initiator into the processing region through one or more filament wires heated to a temperature between about 200° C. and about 450° C., and forming the organic polymer layer. In addition, the organic polymer layer is ashable and can be removed from the surface of the substrate when the resist material is removed from the surface of the substrate.

### CROSS-REFERENCE TO RELATED APPLICATIONS

This application claims benefit of U.S. provisional patent application Ser. No. 61/652,131, filed May 25, 2012, which is herein incorporated by reference.

### BACKGROUND OF THE INVENTION

1. Field of the Invention

Embodiments of the present invention generally relate to an organic polymer material layer, its use in integrated circuit fabrication, and an apparatus and a method for depositing the organic polymer material layer.

2. Description of the Related Art

Current demands for increased circuit densities and faster and more efficient circuit components impose the need in shrinking critical dimension and improving the materials used in integrated circuit fabrication. The demands have led to the use of low resistivity conductive materials, such as copper and/or low dielectric constant insulating materials having a dielectric constant less than about 3.8, as well as the need on improving process sequences and process integration.

For example, in process sequences using conventional lithographic techniques, a layer of energy sensitive resist is generally formed over a stack of material layers on a substrate. An image of a pattern may then be introduced into the energy sensitive resist layer. Thereafter, the pattern introduced into the energy sensitive resist layer may be transferred into one or more layers of the material stack formed on the substrate using the layer of energy sensitive resist as a mask. The pattern introduced into the energy sensitive resist may then be transferred into a material layer(s) using a chemical and/or physical etchant. A chemical etchant is generally designed to have a greater etch selectivity for the material layer(s) than for the energy sensitive resist, which generally indicates that the chemical etchant will etch the material layer(s) at a faster rate than it etches the energy sensitive resist. The faster etch rate for the one or more material layers of the stack typically prevents the energy sensitive resist material from being consumed prior to completion of the pattern transfer.

Lithographic imaging tools used in the manufacture of integrated circuits generally employ deep ultraviolet (DUV) imaging wavelengths, i.e., wavelengths of 248 nm or 193 nm, to generate resist patterns. The increased reflective nature of many underlying materials, e.g., polysilicons and metal silicides, may operate to degrade the resulting resist patterns at DUV wavelengths. Thus, an anti-reflective coating (ARC) may be formed over the reflective material layers prior to resist patterning. The ARC generally suppresses the reflections off the underlying material layer during resist imaging, thereby providing more accurate pattern replication in the layer of energy sensitive resist material. For printing features of smaller sizes, immersion lithography using lenses with a high numerical aperture is typically used.

For advanced technology nodes (e.g., below 45 nm), it is demanded to shrink critical dimension (CD) of the features (e.g., reducing line widths and the sizes of the pitches of various vias, contact holes, trenches, and pulling back the ends of the lines, etc). For example, a silicon oxide layer may be deposited on top of a patterned photoresist layer a photoresist feature (e.g., a photoresist contact hole) to achieve desired shrink in the critical dimension. However, the use of the oxide layer creates complexities in process integration.

First of all, to obtain the desired CD shrink in the features of a photoresist pattern, the oxide layer is required to be conformal (e.g., an 100% conformality is desired) and thus difficult to deposit in small-size features. In addition, conventional deposition processes, such as plasma enhanced chemical vapor deposition (PECVD) is typically not compatible to process a substrate having resist materials as the heat and ion-energy generated during PECVD tend to deform resist patterns. Conventional physical vapor deposition (PVD) and chemical vapor deposition (CVD) processes requires high deposition temperatures and are not able to maintain the properties of the function groups in precursor compounds. Further, after the photoresist pattern has been transferred to the underlying material layers (e.g., an ARC layer), the removal of the oxide layer and the underlying ARC layer is quite challenging and may involve additional etching and cleaning processes, as well as the use of different dry etch and wet etch chemistries, and cleaning solutions.

Accordingly, there is a need in the art for a novel process sequence to effectively shrink the critical dimension (CD) and reducing feature size. There is also a need in the art for a novel sacrificial layer that can be deposited conformally and at a low temperature during photoresist patterning.

### SUMMARY OF THE INVENTION

Embodiments of the present invention generally relate to the deposition of a conformal sacrificial polymer film on a surface of a substrate having at least a photo-resist pattern or features thereon in a hot-wire CVD reactor in order to shrink the critical dimension of the photo-resist pattern. In one embodiment, a method of processing a substrate includes positioning the substrate onto a substrate support assembly of a process chamber, wherein at least a portion of the surface of the substrate comprises a resist material and at least another portion of the surface of the substrate comprises an anti-reflective coating material, depositing an organic polymer layer over the surface of the substrate inside the process chamber using a CVD technique, etching a portion of the organic polymer layer from the surface of the substrate, etching a portion of the anti-reflective coating material from the surface of the substrate, and removing the resist material from the surface of the substrate. The CVD technique includes flowing a monomer into a processing region of the process chamber at a temperature of between about 55° C. and about 75° C., flowing an initiator into the processing region through one or more filament wires heated to a temperature between about 200° C. and about 450° C., and forming the organic polymer layer from the monomer.

The monomer is selected from a group consisting of ethyleneglycol diacrylate, t-butylacrylate, N,N-dimethylacrylamide, vinylimidazole, 1-3-diethynylbenzene, phenylacetylene, N,N-dimethylaminoethylmethacrylate, divinylbenzene, glycidyl methacrylate, ethyleneglycol dimethacrylate, tetrafluoroethylene, dimethylaminomethylstyrene, perfluoroalkyl ethylmethacrylate, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 2-hydroxyethyl methacrylate, methacrylic acid, 3,4-ethylenedioxythiophene, and combinations thereof.

The initiator is selected from the group consisting of perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), benzophenone, and combinations thereof.

The organic polymer layer may be an polymer selected from the group consisting of poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

In another embodiment, a method is provided that includes positioning a substrate onto a substrate support assembly of a process chamber, flowing a monomer containing gas (or vapor) into a processing region of the process chamber, and depositing an organic polymer layer over the surface of the substrate inside the process chamber using the monomer containing gas. At least a portion of the surface of the substrate includes a resist material and at least another portion of the surface of the substrate includes an anti-reflective coating material. The method further includes etching a portion of the organic polymer layer and a portion of the anti-reflective coating material from the surface of the substrate. The method further includes removing completely or at least a portion of the resist material and/or the organic polymer layer from the surface of the substrate.

In yet another embodiment, an apparatus for processing a substrate is provided. The apparatus includes a CVD chamber configured to deposit an organic polymer layer over a surface of the substrate having a resist material and an anti-reflective coating material thereon and an etch chamber configured to remove the organic polymer layer from the surface of the substrate. The CVD chamber includes a first source box configured to deliver a monomer into a processing region of the CVD chamber; and a filament adapted to be heated at a temperature between about 200° C. and 450° C. The apparatus further includes an ash chamber configured to remove the resist material and the organic polymer layer from the surface of the substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B illustrate process integration of one embodiment of forming an organic polymer layer during photoresist patterning.

FIG. 2 illustrates a method of one embodiment of forming an organic polymer layer using a CVD technique.

FIG. 3A illustrates a process integration sequence of one embodiment of forming an organic polymer layer during a process sequence of photoresist patterning, lithography, and etching.

FIG. 3B illustrates substrates features that have been processed through a process sequence of photoresist patterning, lithography, and etching in an effort to shrink the critical dimension of feature sizes.

Appendix A illustrates one or more aspects of the invention.

### DETAILED DESCRIPTION OF THE INVENTION

Embodiments of the present invention provide a method and apparatus for forming a conformal sacrificial polymer film on a surface of a substrate having at least a photo-resist pattern, or features formed thereon, in a hot-wire CVD reactor in order to shrink the critical dimension of the photo-resist pattern. Polymer hot-wire chemical vapor deposition (PHCVD) is a low-energy process and is able to maintain the function groups in precursors while at the same time deposit ALD-like (atomic layer deposition) conformal films. Certain embodiments described herein include the integration of a conformal organic polymer layer in a process sequence of photoresist patterning, lithography, and pattern etching and transfer.

For example, a polymer thin film can be deposited at low substrate temperature via polymer hot-wire CVD (PHCVD) and used as a sacrificial layer on a photoresist pattern to reduce the critical dimension of substrate features (e.g., contact holes, vias, metal lines, etc). In one example, a methacrylate based homopolymer film (poly(ethylene glycol diacrylate)) is deposited. The resulting film layer is highly conformal over a photoresist pattern and can be easily ashed away by conventional O₂ plasma. The properties of the polymer thin film can be controlled via process conditions, such as the filament temperature, pedestal temperature, pressure and flow rates, etc. PHCVD eliminates the use of plasma and therefore is able to maintain the functionalities in monomer precursors, which can be utilized for subsequent functionalization.

The PHCVD process generally involves in flowing at least a precursor monomer species to form the organic polymer film layer. In some cases, an initiator is flown into the hot wire CVD chamber. The initiator passes through a set of metal wire filaments that are heated and consequently, the initiator dissociates into radicals. The monomer is flown either separately or together with the initiator(s) to adsorb on the surface of the substrate (e.g., a wafer). The activated initiator radicals interact with the surface monomer species to begin the polymerization reaction. Alternatively, the initiator can be passed through a heated shower-head of a CVD process chamber. The heated showerhead is used to activate the initiator and uniformly distribute the initiator radicals for uniform deposition on large area of a substrate. As a result, a solid organic polymer film is formed on the surface of the substrate. Since the process is driven by surface adsorption, step coverage can be modulated by substrate temperature, precursor partial pressures and choice of precursor.

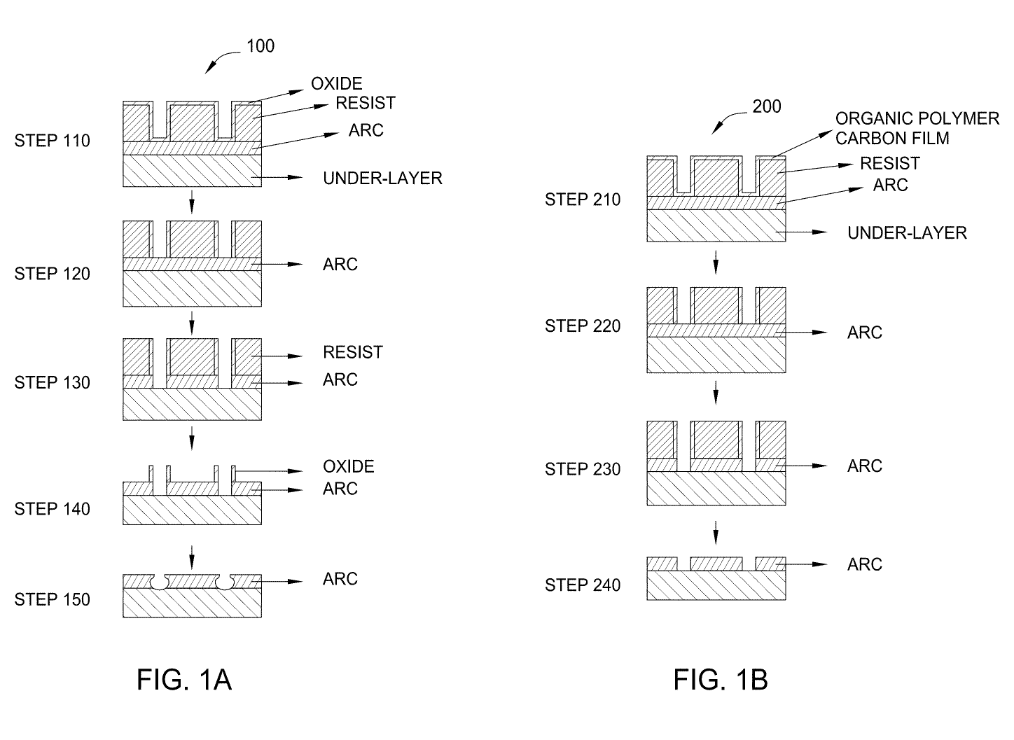

FIG. 1A illustrates a process sequence 100 for conventional photoresist and lithography patterning and the use of an oxide layer in shrinking critical dimension of a contact hole or via. The process sequence 100 includes deposition of an oxide layer over the surface of a substrate having a patterned photoresist material layer at step 110. The oxide layer can be formed conformally by an atomic layer and/or chemical vapor deposition technique.

At step 120, the oxide layer is etched, such as by a wet etch process, and at step 130, an anti-reflective coating (ARC) layer underlying the photoresist material layer is etched, such as by a dry etch process. Accordingly, a photoresist pattern is transferred onto the surface of the substrate.

At step 140, the patterned photoresist material layer is removed, such as by an oxygen plasma ash process. As shown in FIG. 1A, a portion of the oxide layer still remains on the surface of the substrate after ashing the photoresist material layer.

At step 150, after the photoresist material is removed from the surface of the substrate, the oxide layer is then removed from the surface of the substrate, such as by a wet clean process by use of a chemical wet-clean solution.

FIG. 1B illustrates a process sequence 200 for an improved photoresist and lithography patterning and the integration sequence using an organic polymer layer to shrink the critical dimension of a contact hole or via. The process sequence 200 includes deposition of the organic polymer layer over the surface of a substrate having a patterned photoresist material layer at step 210. The organic polymer layer can be formed conformally by a polymer hot wire chemical vapor deposition technique (PHCVD).

At step 220, the organic polymer layer is etched, such as by a dry etch process, and at step 230, an anti-reflective coating (ARC) layer underlying the photoresist material layer is etched, such as by a dry etch process. In one embodiment, the step 220 and 230 can be performed at the same time and/or in-situ. Accordingly, a photoresist pattern is transferred onto the surface of the substrate.

At step 240, the patterned photoresist material layer is removed, such as by an oxygen plasma ash process. As shown in FIG. 1B, the organic polymer layer can be removed at the same time. In an alternative embodiment, the organic polymer layer can be removed prior to or at different time when the photoresist material layer is removed. This is because the deposited organic polymer layer is ashable by most photoresist ashing processes. Accordingly, the integration of the organic polymer layer involves less process steps.

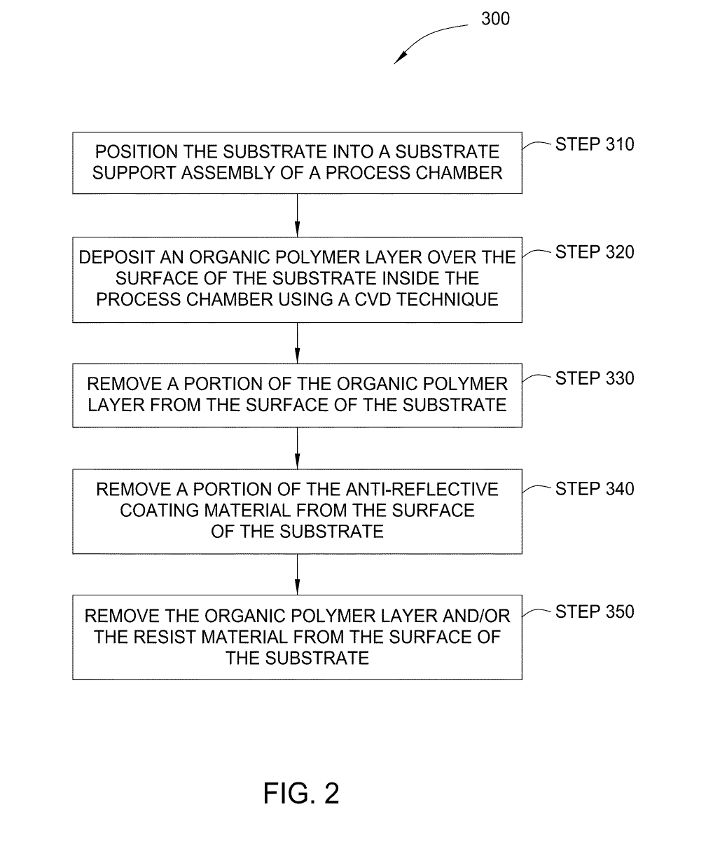

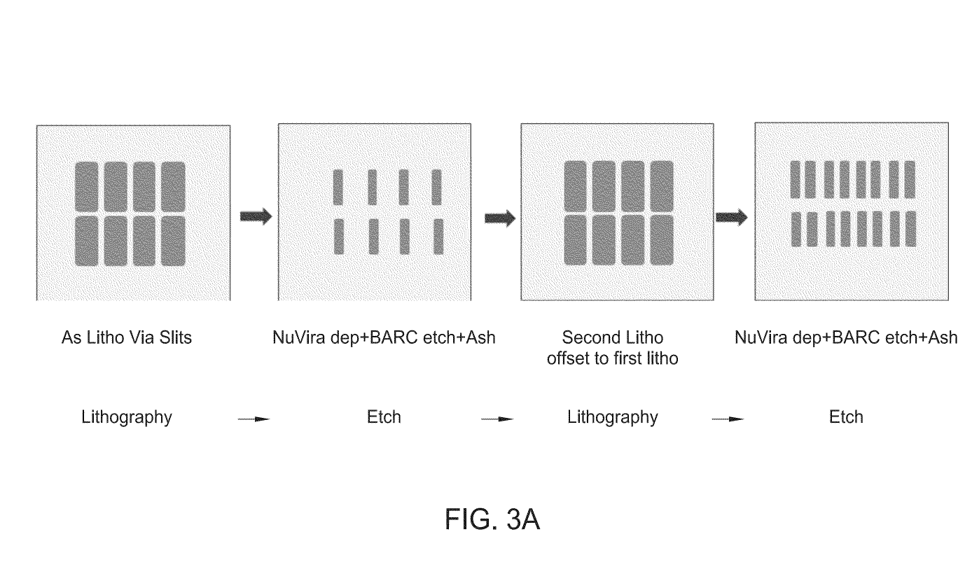

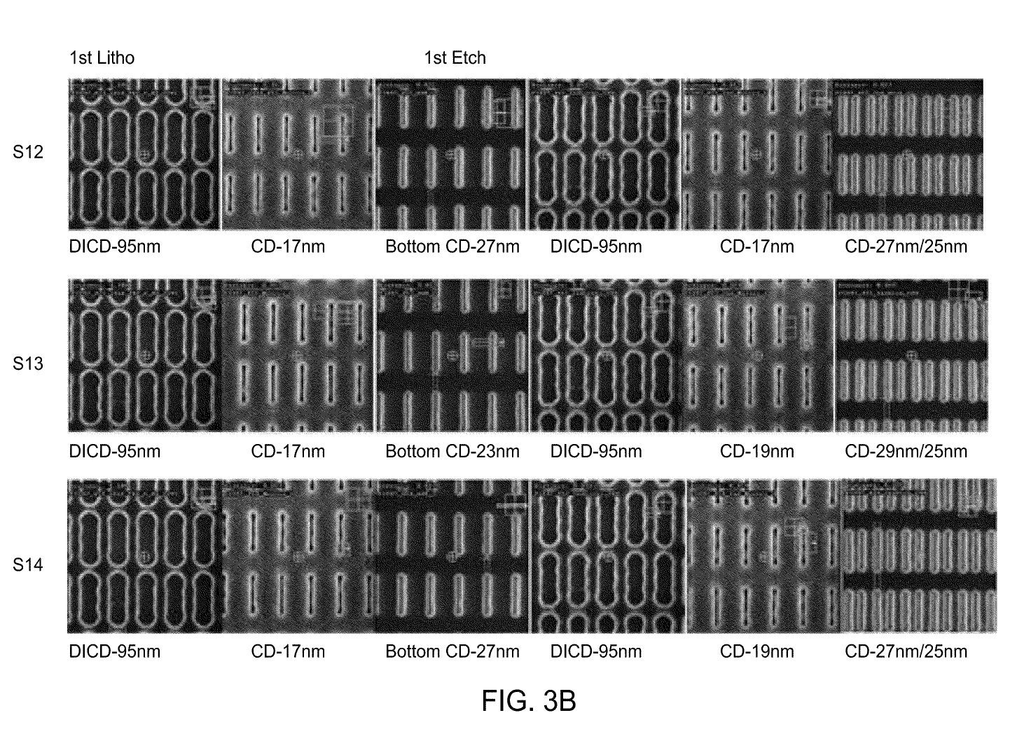

FIG. 2 illustrates a method of one embodiment of forming an organic polymer layer using a CVD technique. The results of using the deposited organic polymer layer to shrink the critical dimension of features are shown in FIGS. 3A and 3B. In FIG. 2, a method 300 of forming an organic polymer layer over a surface of a substrate is provided.

At step 310 of the method 300, the substrate is positioned onto a substrate support assembly of a process chamber. At least a portion of the surface of the substrate includes a resist material and at least another portion of the surface of the substrate includes an anti-reflective coating material.

At step 320, the organic polymer layer is depositing over the surface of the substrate inside the process chamber using a CVD technique. In one embodiment, the CVD technique includes flowing a monomer into a processing region of the process chamber and forming the organic polymer layer from the monomer. The monomer may be selected from a group consisting of ethyleneglycol diacrylate, t-butylacrylate, N,N-dimethylacrylamide, vinylimidazole, 1-3-diethynylbenzene, phenylacetylene, N,N-dimethylaminoethylmethacrylate, divinylbenzene, glycidyl methacrylate, ethyleneglycol dimethacrylate, tetrafluoroethylene, dimethylaminomethylstyrene, perfluoroalkyl ethylmethacrylate, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 2-hydroxyethyl methacrylate, methacrylic acid, 3,4-ethylenedioxythiophene, and combinations thereof. In one aspect, wherein the monomer is flown into the process chamber at a temperature of between about 55° C. and about 75° C.

In another embodiment, the CVD technique further includes flowing an initiator into the processing region through one or more filament wires heated to a temperature between about 200° C. and about 450° C. The initiator may be selected from the group consisting of perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), benzophenone, and combinations thereof.

Accordingly, an organic polymer is deposited on the surface of the substrate by bonding one or more monomer molecules together into a long chain molecule to form a polymer thereon. The organic polymer layer thus deposited may include an polymer selected from the group consisting of poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

In one aspect, the organic polymer layer is deposited over the surface of the substrate at a substrate temperature of between room temperature and about 75° C. In another aspect, the organic polymer layer is deposited conformally over the surface of the substrate to a thickness between 50 angstroms and 1000 angstroms at a deposition rate of between 10 angstrom per minute and 500 angstroms per minute.

At step 330, a portion of the organic polymer layer is etched from the surface of the substrate. At step 340, a portion of the anti-reflective coating material is etched from the surface of the substrate. The portion of the anti-reflective coating material and the portion of the organic layer are etched at the same time from the surface of the substrate using an etching technique.

Additional steps may include removing the organic polymer layer from the surface of the substrate after etching the anti-reflective coating material.

At step 350, the resist material is removed from the surface of the substrate. In one aspect, the organic polymer layer is removed from the surface of the substrate when the resist material is removed from the surface of the substrate.

FIG. 3A illustrates a process integration sequence according to one embodiment of the invention that includes forming an organic polymer layer during a process sequence that includes photoresist patterning, lithography, and etching.

FIG. 3B illustrates substrate features that have been processed through a process sequence of photoresist patterning, lithography, and etching in shrinking critical dimension of feature sizes.

Another embodiment of the invention provides an apparatus for processing a substrate that includes a CVD chamber configured to deposit an organic polymer layer over a surface of the substrate having a resist material and an anti-reflective coating material disposed thereon, and an etch chamber configured to etch a portion of the organic polymer layer from the surface of the substrate. The CVD chamber may include a first source box configured to deliver a monomer containing gas (or vapor) into a processing region of the first CVD chamber, and a filament adapted to be heated at a temperature between about 200° C. and 450° C.

The apparatus may further include an ashing chamber configured to remove the resist material and the organic polymer layer from the surface of the substrate. While the particular apparatus in which the embodiments described herein can be practiced is not limited, it is particularly beneficial to practice the embodiments in a cluster tool system or a web-based roll-to-roll system, which may be purchased from Applied Materials, Inc., Santa Clara, Calif.

One desirable processing technique that can be used to form the organic polymer layer is a polymer hot-wire chemical vapor deposition process (PHCVD). The polymer hot-wire chemical vapor deposition (PHCVD) techniques used herein may be generally categorized into two types: catalytic and non-catalytic. The methods which use catalyst materials to facilitate and help control the growth of the organic polymer film are referred to as catalytic CVD methods. In one embodiment, the organic polymer film may be formed using catalytic CVD methods, such as hot-wire chemical vapor deposition (HWCVD) also known as hot filament CVD (HWCVD). HWCVD uses a hot filament to chemically decompose source gases. The methods which use no catalyst materials for the organic polymer film growth are referred to as non-catalytic or pyrolytic CVD methods, since only heating, and not catalysis. The catalytic CVD methods often provide greater control over the organic polymer film growth than non-catalytic methods.

The PHCVD growth of the organic polymer film involves heating particles of a catalyst initiator to a high temperature and flowing a carbon source gas, such as a hydrocarbon “CₓH_{y}”, carbon monoxide, or other carbon-containing gas over the catalyst particles for a period of time. The catalyst particles reside on a surface of the substrate where a conductive substrate is used or on the surface of the current collector. The catalyst particles are typically nanometer scale in size, and the diameters or widths of the graphitic nanofilaments are often closely related to the sizes of the catalyst particles. The catalyst may be deposited on the surface of the substrate or the current collector using wet or dry deposition. Dry deposition techniques include but are not limited to sputtering, thermal evaporation, and chemical vapor deposition (CVD), wet deposition techniques include, but are not limited to the techniques of wet catalyst, colloidal catalyst solutions, sol-gel, electrochemical plating, and electroless plating.

The diameter, length and alignment of the deposited organic polymer film may be controlled by controlling the CVD growth parameters. The growth parameters include but are not limited to carbon source gas or liquid materials, initiator materials, carrier gas, growth temperature, growth pressure, and growth time. For catalytic CVD growth, additional growth parameters may include catalyst parameters such as catalyst size, shape, composition, and catalyst precursors. The parameter ranges and options for catalytic CVD growth, excluding catalyst parameters, may, in general, be applicable to the non-catalytic CVD growth of graphitic nanofilaments, although higher temperatures may be used for the non-catalytic CVD methods.

Generally, the temperatures for the PHCVD growth of the organic polymer film may range from about 200 degrees Celsius (° C.) to about 450 degrees Celsius, although temperatures lower than 600° C. may be used. The growth pressures may range from about 100 mTorr to about 1 atmosphere, but more preferably from about 0.1 Torr to about 100 Torr, although lower or higher pressures may also be used. The growth time or “residence time” depends in part on the desired thickness of the organic polymer film, with longer growth times producing longer lengths. The growth time may range from about ten seconds to many hours, but more typically from about ten minutes to several hours.

The temperature of the filament for the PHCVD process is generally dependent upon the initiator source gas. In one embodiment, the temperature of the filament for the PHCVD growth of the electrolytic polymer structure may range from about 200 degrees Celsius (° C.) to about 600 degrees Celsius (° C.). In one embodiment, the temperature of the substrate may be about room temperature (e.g. about 20 to 25° C.).

In one embodiment, the growth pressure may range from about 100 mTorr to about 1 atmosphere. In another embodiment, the growth pressure may range from about 400 mTorr to about 700 mTorr. In another embodiment, the growth pressure may be less than 1,000 mTorr. In another embodiment, the growth pressure may be less than 400 mTorr, although lower or higher pressures may also be used.

In one embodiment, the monomer source gas may include tetrafluoroethylene. In general, the monomer source gas may comprise any monomer-containing gas or gases, and the monomer source gas may be obtained from liquid or solid precursors to form the monomer-containing gas or gases. In one embodiment, the monomer source gas is selected from the group comprising acrylate monomers, methacrylate monomers, and styrenic monomers, 1-vinyl-2-pyrrolidone, maleic anhydride, and trivinyltri-methylcyclotrisiloxane. In one embodiment, the monomer source gas is selected from the group comprising tetrafluoroethylene, glycidyl methacrylate (GMA), dimethylaminomethylstyrene (DMAMS), perfluoroalkyl ethylmethacrylate, trivinyltrimethoxy-cyclotrisiloxane, furfuryl methacrylate, cyclohexyl methacrylate-co-ethylene glycol di methacrylate, pentafluorophenyl methacrylate-co-ethylene glycol diacrylate, 2-hydroxyethyl methacrylate-co-ethylene glycol diacrylate, methacrylic acid-co-ethylene glycol dimethacrylate, 3,4-ethylenedioxythiophene, organosiloxanes, and combinations thereof. An auxiliary gas may be used with the monomer source gas to facilitate the growth process. The auxiliary gas may comprise one or more gases, such as carrier gases, inert gases, reducing gases (e.g., hydrogen, ammonia), dilution gases, or combinations thereof, for example. The term “carrier gas” is sometimes used in the art to denote inert gases, reducing gases, and combinations thereof. Some examples of carrier gases are hydrogen, nitrogen, argon, and ammonia.

In one embodiment, the initiator source may include molecules selected from the peroxide and azo class of molecules. In one embodiment, the initiator source gas is selected from the group comprising perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO) and benzophenone. In one embodiment, the initiator source gas may include but is not limited to hydrogen peroxide, alkyl peroxides, aryl peroxides, hydroperoxides, halogens, azo compounds, and combinations thereof. In general, the initiator source gas may comprise any initiator-containing gas or gases, and the initiator source gas may be obtained from liquid or solid precursors for the monomer-containing gas or gases.

In certain embodiments it may be advantageous to further include a gaseous cross-linker. Gaseous cross-linker source gases include In one embodiment, the cross-linking agents include, but are not limited to, 2-ethyl-2(hydroxymethyl)propane-trimethyacrylate (TRIM), acrylic acid, methacrylic acid, trifluoro-methacrylic acid, 2-vinylpyridine, 4-vinylpyridine, 3(5)-vinylpyridine, p-methylbenzoic acid, itaconic acid, 1-vinylimidazole, ethylene glycol dimethacrylate, and combinations thereof.

While the foregoing is directed to embodiments of the present invention, other and further embodiments of the invention may be devised without departing from the basic scope thereof, and the scope thereof is determined by the claims that follow.

1. A method of processing a substrate, comprising:
positioning the substrate on a substrate support assembly of a process chamber, wherein at least a portion of the surface of the substrate comprises a resist material and at least another portion of the surface of the substrate comprises an anti-reflective coating material;
depositing an organic polymer layer over the surface of the substrate inside the process chamber using a CVD technique;
etching a portion of the organic polymer layer from the surface of the substrate;
etching a portion of the anti-reflective coating material from the surface of the substrate; and
removing the resist material from the surface of the substrate.

2. The method of claim 1, wherein the CVD technique comprises:
flowing a monomer into a processing region of the process chamber and forming the organic polymer layer from the monomer.

3. The method of claim 2, wherein the monomer is selected from a group consisting of ethyleneglycol diacrylate, t-butylacrylate, N,N-dimethylacrylamide, vinylimidazole, 1-3-diethynylbenzene, phenylacetylene, N,N-dimethylaminoethylmethacrylate, divinylbenzene, glycidyl methacrylate, ethyleneglycol dimethacrylate, tetrafluoroethylene, dimethylaminomethylstyrene, perfluoroalkyl ethyl methacrylate, trivinyltrimethoxy-cyclotrisiloxane, furfuryl methacrylate, cyclohexyl methacrylate-co-ethylene glycol di methacrylate, pentafluorophenyl methacrylate-co-ethylene glycol diacrylate, 2-hydroxyethyl methacrylate, methacrylic acid, 3,4-ethylenedioxythiophene, and combinations thereof.

4. The method of claim 2, wherein the monomer is flown into the process chamber at a temperature of between about 55° C. and about 75° C.

5. The method of claim 2, wherein the CVD technique further comprises:
flowing an initiator into the processing region through one or more filament wires heated to a temperature between about 200° C. and about 450° C.

6. The method of claim 4, wherein the initiator is selected from the group consisting of perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), benzophenone, and combinations thereof.

7. The method of claim 1, wherein the organic polymer layer comprises an polymer selected from the group consisting of poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

8. The method of claim 1, wherein the organic polymer layer is deposited over the surface of the substrate at a substrate temperature of between room temperature and about 75° C.

9. The method of claim 1, wherein the organic polymer layer is deposited conformally over the surface of the substrate to a thickness between 50 angstroms and 1000 angstroms at a deposition rate of between 10 angstrom per minute and 500 angstroms per minute.

10. The method of claim 1, wherein the portion of the anti-reflective coating material and the portion of the organic layer are etched at the same time from the surface of the substrate using an etching technique.

11. The method of claim 1, further comprising:
removing the organic polymer layer from the surface of the substrate after etching the anti-reflective coating material.

12. The method of claim 1, wherein the organic polymer layer is removed from the surface of the substrate when the resist material is removed from the surface of the substrate.

13. A method of processing a substrate, comprising:
positioning the substrate on a substrate support assembly of a process chamber, wherein at least a portion of the surface of the substrate comprises a resist material and at least another portion of the surface of the substrate comprises an anti-reflective coating material;
flowing a monomer into a processing region of the process chamber;
depositing an organic polymer layer over the surface of the substrate inside the process chamber using the monomer;
etching a portion of the organic polymer layer from the surface of the substrate;
etching a portion of the anti-reflective coating material from the surface of the substrate; and
removing the resist material from the surface of the substrate.

14. The method of claim 13, wherein the monomer is selected from a group consisting of ethyleneglycol diacrylate, t-butylacrylate, N,N-dimethylacrylamide, vinylimidazole, 1-3-diethynylbenzene, phenylacetylene, N,N-dimethylaminoethylmethacrylate, divinylbenzene, glycidyl methacrylate, ethyleneglycol dimethacrylate, tetrafluoroethylene, dimethylaminomethylstyrene, perfluoroalkyl ethyl methacrylate, trivinyltrimethoxy-cyclotrisiloxane, furfuryl methacrylate, cyclohexyl methacrylate-co-ethylene glycol dimethacrylate, pentafluorophenyl methacrylate-co-ethylene glycol diacrylate, 2-hydroxyethyl methacrylate, methacrylic acid, 3,4-ethylenedioxythiophene, and combinations thereof.

15. The method of claim 13, wherein the monomer is flown into the process chamber at a temperature of between about 55° C. and about 75° C.

16. The method of claim 13, further comprising:
flowing an initiator selected from the group consisting of perfluorooctane sulfonyl fluoride (PFOS), perfluorobutane-1-sulfonyl fluoride (PFBS), triethylamine (TEA), tert-butyl peroxide (TBPO), 2,2′-azobis (2-methylpropane), tert-amyl peroxide (TAPO), benzophenone, and combinations thereof into the processing region through one or more filament wires heated to a temperature between about 200° C. and about 450° C.

17. The method of claim 13, wherein the organic polymer layer comprises an polymer selected from the group consisting of poly(ethyleneglycol diacrylate), poly(t-butylacrylate), poly N,N-dimethylacrylamide, poly(vinylimidazole), poly(1-3-diethynylbenzene), poly(phenylacetylene), poly(N,N-dimethylaminoethylmethacrylate) (p(DMAM), poly (divinylbenzene), poly(glycidyl methacrylate) (p(GMA)), poly (ethyleneglycol dimethacrylate), poly (tetrafluoroethylene), poly(tetrafluoroethylene) (PTFE), poly(dimethylaminomethylstyrene) (p(DMAMS), poly(perfluoroalkyl ethyl methacrylate), poly(trivinyltrimethoxy-cyclotrisiloxane), poly(furfuryl methacrylate), poly(cyclohexyl methacrylate-co-ethylene glycol dimethacrylate), poly(pentafluorophenyl methacrylate-co-ethylene glycol diacrylate), poly(2-hydroxyethyl methacrylate-co-ethylene glycol diacrylate), poly(methacrylic acid-co-ethylene glycol dimethacrylate), poly(3,4-ethylenedioxythiophene), and combinations thereof.

18. The method of claim 13, further comprising removing the organic polymer layer from the surface of the substrate when the resist material is removed from the surface of the substrate.

19. The method of claim 13, wherein the portion of the anti-reflective coating material and the portion of the organic layer are etched at the same time from the surface of the substrate using an etching technique.

20. The method of claim 13, wherein the organic polymer layer is deposited over the surface of the substrate at a substrate temperature of between room temperature and about 75° C.

21. The method of claim 13, wherein the organic polymer layer is deposited conformally over the surface of the substrate to a thickness between 50 angstroms and 1000 angstroms at a deposition rate of between 10 angstrom per minute and 500 angstroms per minute.

22. An apparatus for processing a substrate, comprising:
a CVD chamber configured to deposit an organic polymer layer over a surface of the substrate having a resist material and an anti-reflective coating material thereon, the CVD chamber comprising:
a first source box configured to deliver a monomer into a processing region of the first CVD chamber; and
a filament adapted to be heated at a temperature between about 200° C. and 450° C.; and
an etch chamber configured to etch a portion of the organic polymer layer from the surface of the substrate.

23. The apparatus of claim 22, further comprising:
an ash chamber configured to remove the resist material and the organic polymer layer from the surface of the substrate.
